(19) United States
(12) Patent Application Publication
(10) Pub. No.: US 2024/0194668 A1
(43) Pub. Date: Jun. 13, 2024

(54) ELECTROSTATIC DISCHARGE PROTECTION STRUCTURE

(71) Applicant: UNITED MICROELECTRONICS CORP., Hsin-Chu City (TW)

(72) Inventors: Yu-Hsuan Lin, Kaohsiung City (TW); Hou-Jen Chiu, Taichung City (TW); Mei-Ling Chao, Tainan City (TW); Tien-Hao Tang, Hsinchu City (TW); Kuan-Cheng Su, Taipei City (TW)

(73) Assignee: UNITED MICROELECTRONICS CORP., Hsin-Chu City (TW)

(21) Appl. No.: 18/105,256

(22) Filed: Feb. 3, 2023

(30) Foreign Application Priority Data
Dec. 12, 2022 (CN) 202211596097.8

(51) Int. Cl. H01L 27/02; H01L 27/082; H01L 29/08

(52) U.S. Cl. CPC H01L 27/0259; H01L 27/082; H01L 29/0808; H01L 29/0821; H01L 29/735

(57) ABSTRACT

An electrostatic discharge protection structure includes a semiconductor substrate and a first n-type well region, a p-type well region, a first p-type doped region, a second p-type doped region, and an isolation structure disposed in the semiconductor substrate. The p-type well region is located adjacent to the first n-type well region. The first p-type doped region and the second p-type doped region are located above the first n-type well region and the p-type well region, respectively. A first portion of the isolation structure is located between the first p-type doped region and the second p-type doped region in a horizontal direction. An edge of the first n-type well region is located under the first portion. A distance between the first p-type doped region and the edge of the first n-type well region in the horizontal direction is less than a length of the first portion in the horizontal direction.

### BACKGROUND OF THE INVENTION

### 1. Field of the Invention

The present invention relates to an electrostatic discharge (ESD) protection structure, and more particularly, to an electrostatic discharge protection structure including an isolation structure.

### 2. Description of the Prior Art

Electrostatic discharge (ESD) is a discharge effect where charges accumulate on a non-conductor or an ungrounded conductor and travel rapidly through a discharge path in a short period of time, and ESD can cause damage to integrated circuits. Generally, the human bodies, the machines for IC packaging, the instruments for testing the integrated circuit, etc. are all common charged bodies. When the charged body is in contact with the chip or wafer, the charged body will discharge to the chip or wafer. The transient power of electrostatic discharge can cause damage or failure of the wafer or integrated circuits within the wafer. Therefore, ESD protection structures are provided in integrated circuits for improving the above-mentioned problems.

### SUMMARY OF THE INVENTION

An electrostatic discharge protection (ESD) structure is provided in the present invention. An isolation structure is disposed between a first p-type doped region located above an n-type well region and a second p-type doped region located above a p-type well region, and a distance between the first p-type doped region and an edge of the n-type well region is controlled for improving operation characteristics of the electrostatic discharge protection structure.

According to an embodiment of the present invention, an electrostatic discharge protection structure is provided. The electrostatic discharge protection structure includes a semiconductor substrate, a first n-type well region, a p-type well region, a first p-type doped region, a second p-type doped region, and an isolation structure. The first n-type well region, the p-type well region, the first p-type doped region, the second p-type doped region, and the isolation structure are disposed in the semiconductor substrate. The p-type well region is located adjacent to the first n-type well region, the first p-type doped region is located above the first n-type well region in a vertical direction, and the second p-type doped region is located above the p-type well region in the vertical direction. A first portion of the isolation structure is located between the first p-type doped region and the second p-type doped region in a first horizontal direction, an edge of the first n-type well region is located under the first portion of the isolation structure in the vertical direction, and a distance between the first p-type doped region and the edge of the first n-type well region in the first horizontal direction is less than a length of the first portion of the isolation structure in the first horizontal direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating an electrostatic discharge protection structure according to a first embodiment of the present invention.

FIG. 2 is a schematic equivalent circuit diagram of an electrostatic discharge protection structure according to an embodiment of the present invention.

FIG. 3 is a schematic drawing illustrating a top view of an electrostatic discharge protection structure according to a second embodiment of the present invention.

FIG. 4 is a schematic drawing illustrating a cross-sectional view of the electrostatic discharge protection structure according to the second embodiment of the present invention.

FIG. 5 is a schematic drawing illustrating an electrostatic discharge protection structure according to a third embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

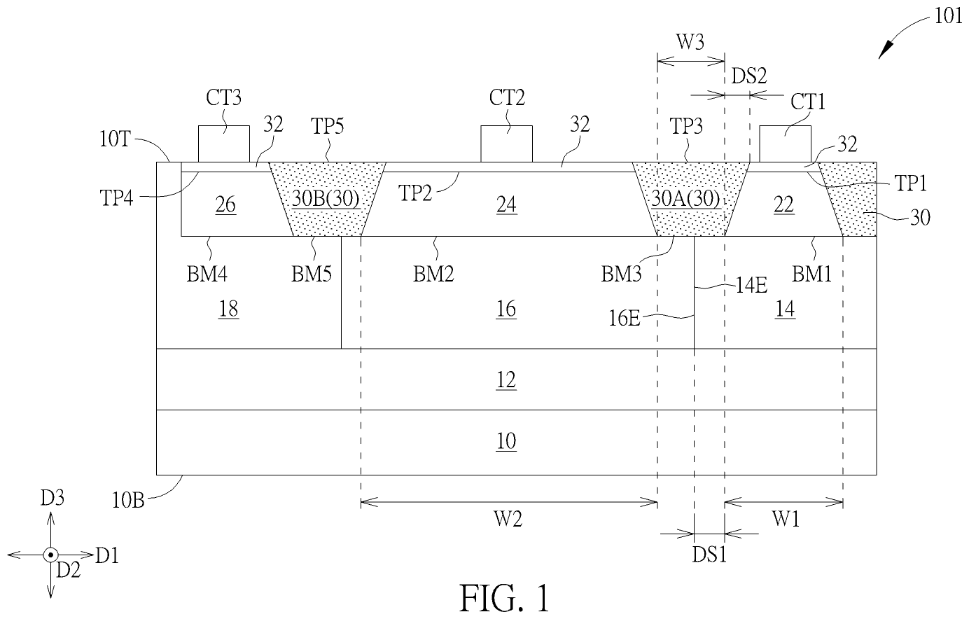

Please refer to FIG. 1. FIG. 1 is a schematic drawing illustrating an electrostatic discharge (ESD) protection structure 101 according to a first embodiment of the present invention. As shown in FIG. 1, the electrostatic discharge protection structure 101 includes a semiconductor substrate 10, a first n-type well region 14, a p-type well region 16, a first p-type doped region 22, a second p-type doped region 24, and an isolation structure 30. The first n-type well region 14, the p-type well region 16, the first p-type doped region 22, the second p-type doped region 24, and the isolation structure 30 are disposed in the semiconductor substrate 10. The p-type well region 16 is located adjacent to the first n-type well region 14, the first p-type doped region 22 is located above the first n-type well region 14 in a vertical direction D3, and the second p-type doped region 24 is located above the p-type well region 16 in the vertical direction D3. A first portion 30A of the isolation structure 30 is located between the first p-type doped region 22 and the second p-type doped region 24 in a first horizontal direction D1, an edge 14E of the first n-type well region 14 is located under the first portion 30A of the isolation structure 30 in the vertical direction D3, and a distance DS1 between the first p-type doped region 22 and the edge 14E of the first n-type well region 14 in the first horizontal direction D1 is less than a length of the first portion 30A of the isolation structure 30 in the first horizontal direction D1 (such as a width W3 illustrated in FIG. 1). The operation characteristics of the electrostatic discharge protection structure 101 may be improved by the allocations of the parts in the electrostatic discharge protection structure 101 described above and controlling the distance DS1 between the first p-type doped region 22 and the edge 14E of the first n-type well region 14. For instance, punch-through breakdown may be generated more easily, and trigger voltage and/or breakdown voltage of the electrostatic discharge protection structure may be lowered accordingly for improving ESD protection efficiency, but not limited thereto.

In some embodiments, the vertical direction D3 described above may be regarded as a thickness direction of the semiconductor substrate 10. The semiconductor substrate 10 may have a top surface 10T and a bottom surface 10B opposite to the top surface 10T in the vertical direction D3. The first p-type doped region 22, the second p-type doped region 24, and the isolation structure 30 described above may be disposed at a side adjacent to the top surface 10T. Horizontal directions substantially orthogonal to the vertical direction D3 (such as the first horizontal direction D1, a second horizontal direction D2, and other directions orthogonal to the vertical direction D3) may be substantially parallel with the top surface 10T and/or the bottom surface 10B of the semiconductor substrate 10, but not limited thereto. In this description, a distance between the bottom surface 10B of the semiconductor substrate 10 and a relatively higher location and/or a relatively higher part in the vertical direction D3 is greater than a distance between the bottom surface 10B of the semiconductor substrate 10 and a relatively lower location and/or a relatively lower part in the vertical direction D3. The bottom or a lower portion of each component may be closer to the bottom surface 10B of the semiconductor substrate 10 in the vertical direction D3 than the top or upper portion of this component. Another component disposed above a specific component may be regarded as being relatively far from the bottom surface 10B of the semiconductor substrate 10 in the vertical direction D3, and another component disposed under a specific component may be regarded as being relatively closer to the bottom surface 10B of the semiconductor substrate 10 in the vertical direction D3.

In some embodiments, the electrostatic discharge protection structure 101 may further include a deep n-type well region 12, a second n-type well region 18, and an n-type doped region 26. The second n-type well region 18 may be disposed in the semiconductor substrate 10 and located adjacent to the p-type well region 16, and at least a portion of the p-type well region 16 may be located between the second n-type well region 18 and the first n-type well region 14 in the first horizontal direction D1, but not limited thereto. The deep n-type well region 12 may be disposed in the semiconductor substrate 10, and the first n-type well region 14, the p-type well region 16, and the second n-type well region 18 may be located above the deep n-type well region 12 in the vertical direction D3. In some embodiments, the deep n-type well region 12 may be directly connected with the first n-type well region 14, the p-type well region 16, and the second n-type well region 18, respectively, and the p-type well region 16 may be directly connected with the first n-type well region 14 and the second n-type well region 18 in the horizontal direction, but not limited thereto. The n-type doped region 26 may be disposed in the second n-type well region 18, and a second portion 30B of the isolation structure 30 may be located between the second p-type doped region 24 and the n-type doped region 26 in the first horizontal direction D1.

In some embodiments, the first p-type doped region 22 may be an emitter of a bipolar junction transistor, the second p-type doped region 24 and the p-type well region 16 may be at least a part of a collector of this bipolar junction transistor, and the first n-type well region 14 may be at least a part of a base of this bipolar junction transistor, but not limited thereto. In other words, the first p-type doped region 22, the first n-type well region 14, and the p-type well region 16 (or the p-type well region 16 and the second p-type doped region 24) may constitute a bipolar junction transistor structure, such as a PNP type bipolar junction transistor. In some embodiments, by controlling the distance DS1 between the first p-type doped region 22 and the edge 14E of the first n-type well region 14 in the first horizontal direction D1, the bipolar junction transistor described above may be more easily triggered by punch-through breakdown than avalanche breakdown when the bipolar junction transistor is used for electrostatic discharge protection, and the trigger voltage and/or the breakdown voltage may be lowered accordingly for improving ESD protection efficiency. In some embodiments, the distance DS1 between the first p-type doped region 22 and the edge 14E of the first n-type well region 14 in the first horizontal direction D1 may be equal to or less than 45 nanometers, but not limited thereto.

In some embodiments, each portion of the isolation structure 30 (such as the first portion 30A and the second portion 30B described above) may have an inverted trapezoid structure with substantially wide top and narrow bottom in the cross-sectional view of the electrostatic discharge protection structure 101 (such as FIG. 1). Therefore, a width of a bottom BM3 of the first portion 30A and/or an area of the bottom BM3 of the first portion 30A may be less than a width of a top TP3 of the first portion 30A and/or an area of the top TP3 of the first portion 30A, and a width of a bottom BM5 of the second portion 30B and/or an area of the bottom BM5 of the second portion 30B may be less than a width of a top TP5 of the second portion 30B and/or an area of the top TP5 of the second portion 30B. Relatively, a width of a bottom BM1 of the first p-type doped region 22 (such as a width W1 illustrated in FIG. 1) and/or an area of the bottom BM1 of the first p-type doped region 22 may be greater than a width of a top TP1 of the first p-type doped region 22 and/or an area of the top TP1 of the first p-type doped region 22, a width of a bottom BM2 of the second p-type doped region 24 (such as a width W2 illustrated in FIG. 1) and/or an area of the bottom BM2 of the second p-type doped region 24 may be greater than a width of a top TP2 of the second p-type doped region 24 and/or an area of the top TP2 of the second p-type doped region 24, and a width of a bottom BM4 of the n-type doped region 26 and/or an area of the bottom BM4 of the n-type doped region 26 may be greater than a width of a top TP4 of the n-type doped region 26 and/or an area of the top TP4 of the n-type doped region 26, but not limited thereto. Therefore, in some embodiments, a distance DS2 may exist between the top TP1 of the first p-type doped region 22 and the bottom BM3 of the first portion 30A of the isolation structure 30 in the first horizontal direction D1, and the distance DS1 between the first p-type doped region 22 and the edge 14E of the first n-type well region 14 in the first horizontal direction D1 may be a distance between the bottom BM1 of the first p-type doped region 22 and the edge 14E of the first n-type well region 14 in the first horizontal direction D1, but not limited thereto. In some embodiments, the distance DS1 may be modified according to some design considerations, the distance DS2 is mainly determined by the manufacturing condition of the process for forming the isolation structure 30, and the distance DS2 may be greater than or less than the distance DS1 accordingly. It is worth noting that, in this description, a bottom of a specific component may include the bottommost portion of this component in the vertical direction D3, and a top of a specific component may include the topmost portion of this component in the vertical direction D3.

In some embodiments, the first portion 30A of the isolation structure 30 may be directly connected with the first p-type doped region 22, the second p-type doped region 24, the first n-type well region 14, and the p-type well region 16, and the second portion 30B of the isolation structure 30 may be directly connected with the second p-type doped region 24, the n-type doped region 26, the second n-type well region 18, and the p-type well region 16. An edge 16E of the p-type well region 16 may be located under the first portion 30A of the isolation structure 30 in the vertical direction D3, and the edge 14E of the first n-type well region 14 may be directly connected with the edge 16E of the p-type well region 16. Therefore, the first n-type well region 14 may be directly connected with the first p-type doped region 22, the deep n-type well region 12, and the p-type well region 16, and the p-type well region 16 may be directly connected with the second p-type doped region 24 and the deep n-type well region 12, but not limited thereto. In some embodiments, another edge of the p-type well region 16 and an edge of the second n-type well region 18 may be directly connected with each other and located under the second portion 30B of the isolation structure 30 in the vertical direction D3, and the second n-type well region 18 may be directly connected with the n-type doped region 26 and the deep n-type well region 12, but not limited thereto.

In some embodiments, the bottom BM1 of the first p-type doped region 22 may be higher than the bottom BM3 of the first portion 30A of the isolation structure 30 in the vertical direction D3, or the bottom BM1 and the bottom BM3 may be coplanar. The bottom BM2 of the second p-type doped region 24 may be higher than the bottom BM3 of the first portion 30A of the isolation structure 30 and the bottom BM5 of the second portion 30B of the isolation structure 30 in the vertical direction D3, or the bottom BM2, the bottom BM3, and the bottom BM5 may be coplanar. The bottom BM4 of the n-type doped region 26 may be higher than the bottom BM5 of the second portion 30B of the isolation structure 30 in the vertical direction D3, or the bottom BM4 and the bottom BM5 may be coplanar. In other words, the bottoms of the first p-type doped region 22, the second p-type doped region 24, and the n-type doped region 26 are not lower than the bottom of the isolation structure 30 in the vertical direction D3. In some embodiments, the width W1 of the bottom BM1 of the first p-type doped region 22 may be regarded as a length of the first p-type doped region 22 in the first horizontal direction D1, and the width W2 of the bottom BM2 of the second p-type doped region 24 may be may be regarded as a length of the second p-type doped region 24 in the first horizontal direction D1. The length of the second p-type doped region 24 in the first horizontal direction D1 may be greater than the length of the first p-type doped region 22 in the first horizontal direction D1, and an area of the second p-type doped region 24 in the vertical direction D3 (such as an area of the bottom BM2) may be greater than an area of the first p-type doped region 22 in the vertical direction D3 (such as an area of the bottom BM1) for improving the robustness of the electrostatic discharge protection structure 101, especially when the first p-type doped region 22 and the second p-type doped region 24 are regarded as the emitter and the collector of the bipolar junction transistor, respectively.

In some embodiments, the semiconductor substrate 10 may include a silicon substrate, a silicon germanium substrate, or a semiconductor substrate formed with other suitable materials. The isolation structure 30 may include a single layer or multiple layers of insulation materials, such as an oxide insulation material, a nitride insulation material, or other suitable insulation materials, and the isolation structure 30 may be regarded as a shallow trench isolation structure formed in the semiconductor substrate 10, but not limited thereto. Additionally, the well regions and the doped regions described above may be formed by performing suitable doping processes (such as implantation processes or other doping approaches) to the semiconductor substrate 10. For example, some regions of the semiconductor substrate 10 may be doped with n-type dopants for forming n-type doped regions or n-type well regions, or some regions of the semiconductor substrate 10 may be doped with p-type dopants for forming p-type doped regions or p-type well regions. The n-type dopants described above may include phosphorus (P), arsenic (As), or other suitable n-type doping materials, and the p-type dopants described above may include boron (B), gallium (Ga), or other suitable p-type doping materials. In some embodiments, the first p-type doped region 22 and the second p-type doped region 24 may be p-type heavily doped regions, and the n-type doped region 26 may be an n-type heavily doped region. Therefore, a dopant concentration of the second p-type doped region 24 may be higher than that of the p-type well region 16, and a dopant concentration of the n-type doped region 26 may be higher than that of the second n-type well region 18, but not limited thereto.

In some embodiments, the electrostatic discharge protection structure 101 may further include a plurality of silicide layers 32 and a plurality of contact structures (such as a contact structure CT1, a contact structure CT2, and a contact structure CT3 illustrated in FIG. 1). The silicide layers 32 may be disposed on the first p-type doped region 22, the second p-type doped region 24, and the n-type doped region 26, respectively. The contact structure CT1, the contact structure CT2, and the contact structure CT3 may be disposed on the first p-type doped region 22, the second p-type doped region 24, and the n-type doped region 26 in the vertical direction D3, respectively, and may be electrically connected with the first p-type doped region 22, the second p-type doped region 24, and the n-type doped region 26, respectively, via the corresponding silicide layers 32. The silicide layer 32 may include cobalt-silicide, nickel-silicide, or other suitable electrically conductive metal silicide materials, and each of the contact structures may include a barrier layer (not illustrated) and a low electrical resistivity material (not illustrated) disposed on the barrier layer, but not limited thereto. The low electrical resistivity material may include a material with relatively low electrical resistivity, such as copper, aluminum, tungsten, and so forth, and the barrier layer may include titanium nitride, tantalum nitride, or other suitable electrically conductive barrier materials, but not limited thereto.

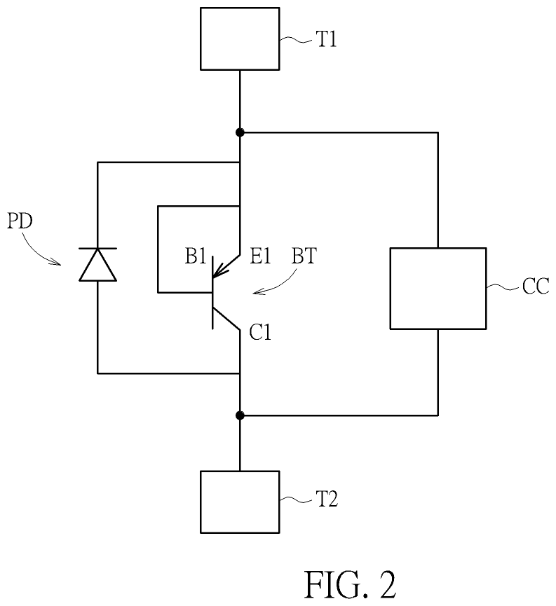

Please refer to FIG. 1 and FIG. 2. FIG. 2 is a schematic equivalent circuit diagram of an electrostatic discharge protection structure according to an embodiment of the present invention. As shown in FIG. 1 and FIG. 2, in some embodiments, the first p-type doped region 22 may be an emitter E1 of a bipolar junction transistor BT, the second p-type doped region 24 and the p-type well region 16 may be at least a part of a collector C1 of the bipolar junction transistor BT, the first n-type well region 14 may be at least a part of a base B1 of the bipolar junction transistor BT, and the bipolar junction transistor BT may be regarded as a lateral bipolar junction transistor (lateral BJT), but not limited thereto. In addition, the emitter E1 and the base B1 of the bipolar junction transistor BT may be electrically connected to a first terminal T1, and the collector C1 of the bipolar junction transistor BT may be electrically connected to a second terminal T2. The bipolar junction transistor BT and a core circuit CC electrically connected with the first terminal T1 and the second terminal T2 may be connected with each other in parallel so as to generate electrostatic discharge protection effect for the core circuit CC. In some embodiments, the contact structure CT1 may be electrically connected with the first p-type doped region 22, and the contact structure CT3 may be electrically connected with the first n-type well region 14 via the silicide layer 32, the n-type doped region 26, the second n-type well region 18, and the deep n-type well region 12. The contact structure CT1 and the contact structure CT3 may be electrically connected with each other via other electrically conductive lines and electrically connected to the first terminal T1, and the base B1 and the emitter E1 of the bipolar junction transistor BT may be electrically connected with each other accordingly. In some embodiments, the first terminal T1 may be a power pad, and the second terminal T2 may be an input/output pad or a ground pad (a pad electrically connected to ground potential). The design of the electrostatic discharge protection circuit may be simplified by the bipolar junction transistor BT. For instance, the area occupied by the electrostatic discharge protection circuit may be reduced because no additional power clamp circuit is required when the bipolar junction transistor BT is applied, but not limited thereto.

As shown in FIG. 1 and FIG. 2, in some embodiments, the p-type well region 16 and the second n-type well region 18 may form a parasite PN diode PD, and a path between the contact structure CT2 and the contact structure CT3 through the second p-type doped region 24, the p-type well region 16, the second n-type well region 18, and the n-type doped region 26 may be regarded as a discharge path via the parasite PN diode PD. In some embodiments, the electrostatic discharge protection structure in the present invention may discharge via different paths when bombarded by electrostatic discharge waveforms in different directions. For example, the electrostatic discharge protection structure may discharge via the path of the bipolar junction transistor BT when bombarded by reverse electrostatic discharge waveforms, and the electrostatic discharge protection structure may discharge via the path of the parasite PN diode PD when bombarded by forward electrostatic discharge waveforms, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

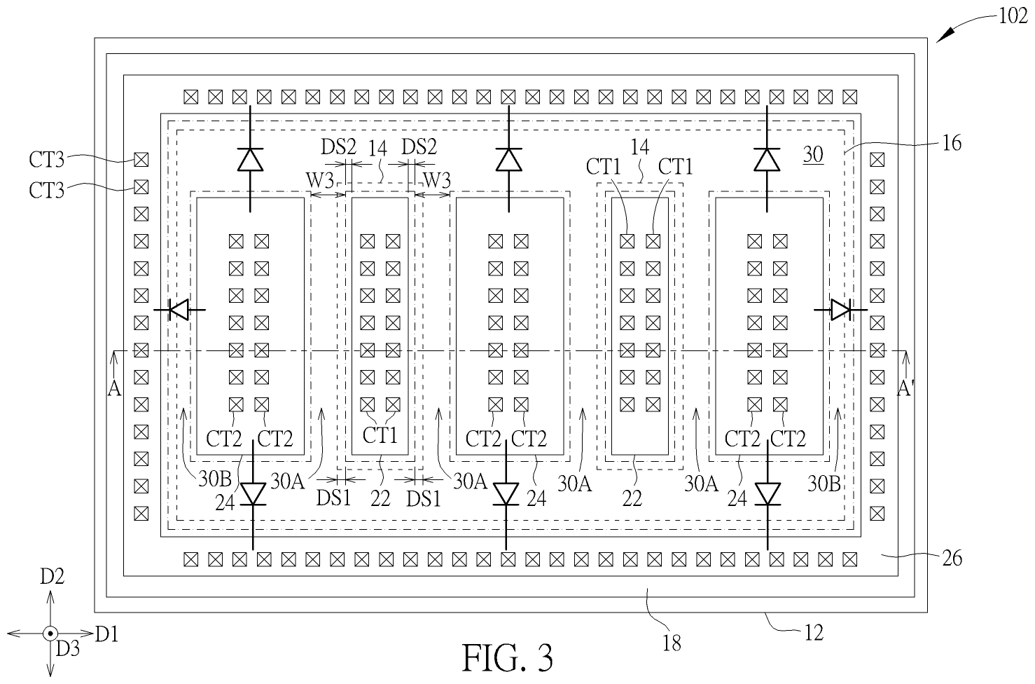

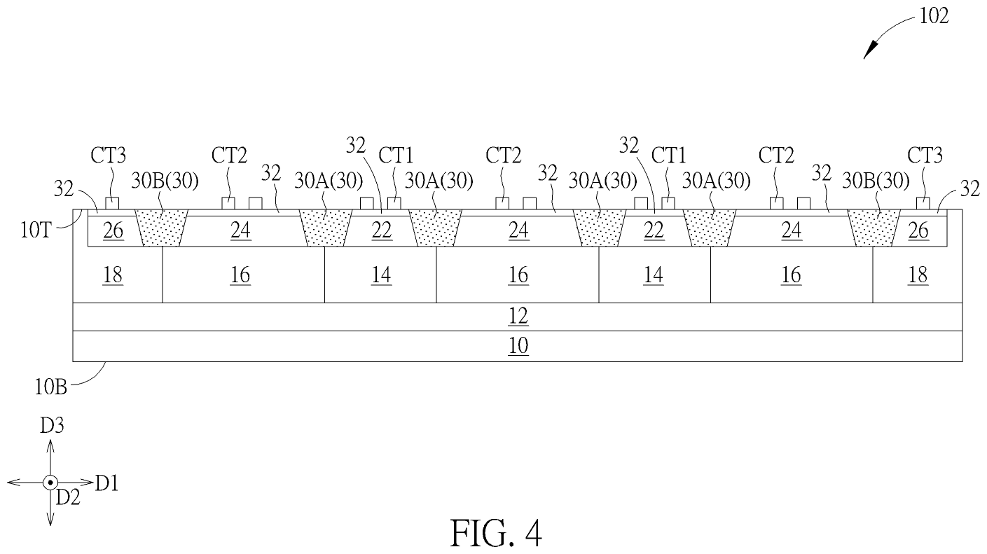

Please refer to FIG. 3 and FIG. 4. FIG. 3 is a schematic drawing illustrating a top view of an electrostatic discharge protection structure 102 according to a second embodiment of the present invention, and FIG. 4 is a schematic drawing illustrating a cross-sectional view of the electrostatic discharge protection structure 102 in this embodiment. In some embodiments, FIG. 3 may be regarded as a layout design schematic drawing of the electrostatic discharge protection structure 102 and some parts of the electrostatic discharge protection structure (such as the silicide layers described above) are not illustrated in FIG. 3, and FIG. 4 may be regarded as a cross-sectional diagram taken along a line A-A′ in FIG. 3, but not limited thereto. As shown in FIG. 3 and FIG. 4, the electrostatic discharge protection structure 102 may include a plurality of the first p-type doped regions 22, a plurality of the second p-type doped regions 24, and a plurality of the first n-type well regions 14. The first p-type doped regions 22 and the second p-type doped regions 24 may be disposed alternately in the first horizontal direction D1, and each of the first p-type doped regions 22, each of the second p-type doped regions 24, and each of the first n-type doped regions 14 may be elongated in the second horizontal direction D2 or directions parallel with the second horizontal direction D2. In some embodiments, the second horizontal direction D2 may be substantially orthogonal to the first horizontal direction D1, but not limited thereto.

In FIG. 3, the dotted line adjacent to each of the first p-type doped regions 22 may be regarded as the edge of the bottom of the isolation structure and the edge of the bottom of the first p-type doped region 22, dotted line adjacent to each of the second p-type doped regions 24 may be regarded as the edge of the bottom of the isolation structure and the edge of the bottom of the second p-type doped region 24, and the dotted line adjacent to the n-type doped region 26 may be regarded as the edge of the bottom of the isolation structure and the edge of the bottom of the f n-type doped region 26. As shown in FIG. 3 and FIG. 4, in the top view of the electrostatic discharge protection structure 102, the isolation structure 30 may surround each of the first p-type doped regions 22 and each of the second p-type doped regions 24 in the horizontal directions (such as the first horizontal direction D1, the second horizontal direction D2, and other horizontal directions orthogonal to the vertical direction D3). Therefore, a portion of the isolation structure 30 may be located between the first p-type doped region 22 and the n-type doped region 26 in the second horizontal direction D2, and another portion of the isolation structure 30 may be located between the second p-type doped region 24 and the n-type doped region 26 in the second horizontal direction D2. In addition, the isolation structure 30 located between the first p-type doped region 22 and the second p-type doped region 24 adjacent to each other in the first horizontal direction D1 may be regarded as the first portion 30A of the isolation structure 30, and the isolation structure 30 located between the second p-type doped region 24 and the n-type doped region 26 adjacent to each other in the first horizontal direction D1 may be regarded as the second portion 30B of the isolation structure 30. The distance DS1 between the bottom of the first p-type doped region 22 and the edge of the first n-type well region 14 in the first horizontal direction D1 may be less than the length of the bottom of the first portion 30A of the isolation structure 30 in the first horizontal direction D1 (such as the width W3), and the distance DS2 may exist between the top of the first p-type doped region 22 and the bottom of the first portion 30A of the isolation structure 30 in the first horizontal direction D1.

In some embodiments, the length of each of the second p-type doped regions 24 in the first horizontal direction D1 (may also be regarded as the width of each of the second p-type doped regions 24) may be greater than the length of each of the first p-type doped regions 22 in the first horizontal direction D1 (may also be regarded as the width of each of the first p-type doped regions 22), the area of each of the second p-type doped regions 24 in the vertical direction D3 may be greater than the area of each of the first p-type doped regions 22 in the vertical direction D3, or the total area of the second p-type doped regions 24 in the vertical direction D3 may be greater than the total area of the first p-type doped regions 22 in the vertical direction D3 for improving the robustness of the electrostatic discharge protection structure 102. Additionally, in the top view of the electrostatic discharge protection structure 102, the p-type well region 16 may surround each of the first n-type well regions 14 in the horizontal directions (such as the first horizontal direction D1, the second horizontal direction D2, and other horizontal directions orthogonal to the vertical direction D3), the second n-type well region 18 may surround the first n-type well regions 14 and the p-type well region 16 in in the horizontal directions, and a portion of the p-type well region 16 may be located between the first n-type well region 14 and the second n-type well region 18 in the second horizontal direction D2 accordingly, but not limited thereto. In some embodiments, the first p-type doped regions 22 may be electrically connected with one another via the first contact structures CT1 and other electrically conductive lines, and the second p-type doped regions 24 may be electrically connected with one another via the first contact structures CT2 and other electrically conductive lines, but not limited thereto.

In some embodiments, the first p-type doped regions 22, the first n-type well regions 14, and the p-type well region 16 (or the p-type well region 16 and the second p-type doped regions 24) may form a bipolar junction transistor (such as the bipolar junction transistor BT illustrated in FIG. 2 described above), and the p-type well region 16 and the second n-type well region 18 may form a parasite PN diode (such as the parasite PN diode illustrated in FIG. 2 described above). A path between the contact structure CT1 and the contact structure CT2 through the first p-type doped region 22, the first n-type well region 14, the p-type well region 16, and the second p-type doped region 24 may be regarded as a discharge path via the bipolar junction transistor, and a path between the contact structure CT2 and the contact structure CT3 through the second p-type doped region 24, the p-type well region 16, the second n-type well region 18, and the n-type doped region 26 may be regarded as a discharge path via the parasite PN diode.

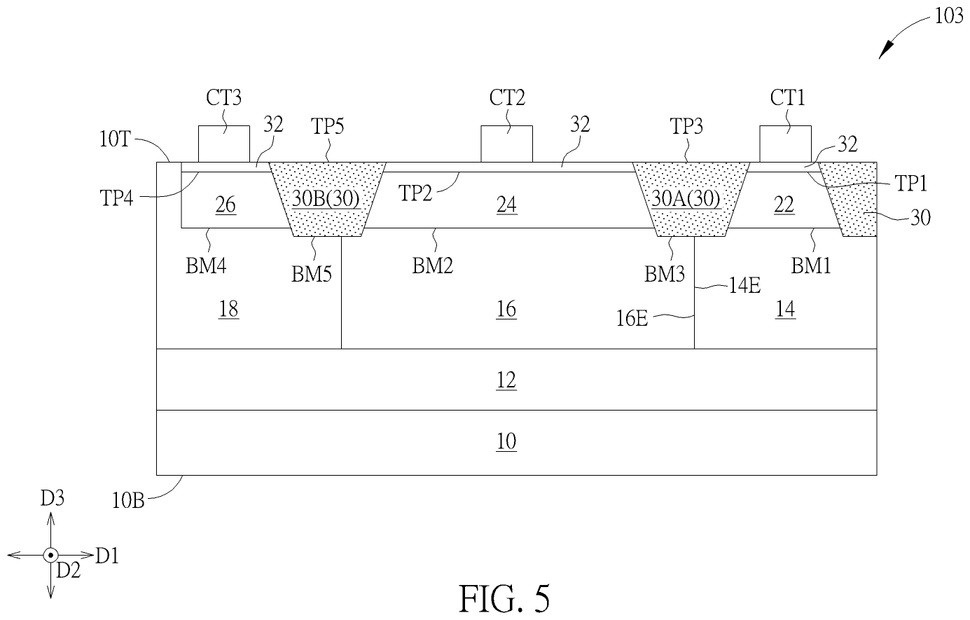

Please refer to FIG. 5. FIG. 5 is a schematic drawing illustrating an electrostatic discharge protection structure 103 according to a third embodiment of the present invention. As shown in FIG. 5, in the electrostatic discharge protection structure 103, the bottom BM1 of the first p-type doped region 22 may be higher than the bottom BM3 of the first portion 30A of the isolation structure 30 in the vertical direction D3, the bottom BM2 of the second p-type doped region 24 may be higher than the bottom BM3 of the first portion 30A of the isolation structure 30 and the bottom BM5 of the second portion 30B of the isolation structure 30 in the vertical direction D3, and the bottom BM4 of the n-type doped region 26 may be higher than the bottom BM5 of the second portion 30B of the isolation structure 30 in the vertical direction D3. In other words, the bottom of the isolation structure 30 (such as the bottom BM3 and/or the bottom BM5) may be lower than the interface between the first p-type doped region 22 and the first n-type well region 14, the interface between the second p-type doped region 24 and the p-type well region 16, and the interface between the n-type doped region 26 and the second n-type well region 18 in the vertical direction D3. It is worth noting that the relative relationship between the doped regions and the isolation structure in this embodiment may also be applied to other embodiments of the present invention (such as being combined with the layout design of the second embodiment described above) according to some design considerations. Additionally, in some embodiments, the bottom BM1 of the first p-type doped region 22, the bottom BM2 of the second p-type doped region 24, and the bottom BM4 of the n-type doped region 26 may be lower than the bottom BM3 of the first portion 30A of the isolation structure 30 and the bottom BM5 of the second portion 30B of the isolation structure 30 in the vertical direction D3 according to some design considerations.

To summarize the above descriptions, according to the electrostatic discharge protection structure in the present invention, the first p-type doped region and the second p-type doped region are disposed above the first n-type well region and the p-type well region adjacent to each other, respectively, and the isolation structure is disposed between the first p-type doped region and the second p-type doped region for forming the lateral bipolar junction transistor in the semiconductor substrate. In addition, by controlling the distance between the first p-type doped region and the edge of the first n-type well region, the trigger voltage and/or the breakdown voltage of the lateral bipolar junction transistor may be lowered, and the electrostatic discharge protection efficiency of the electrostatic discharge protection structure may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electrostatic discharge (ESD) protection structure, comprising:
a semiconductor substrate;
a first n-type well region disposed in the semiconductor substrate;
a p-type well region disposed in the semiconductor substrate and located adjacent to the first n-type well region;
a first p-type doped region disposed in the semiconductor substrate and located above the first n-type well region in a vertical direction;
a second p-type doped region disposed in the semiconductor substrate and located above the p-type well region in the vertical direction; and
an isolation structure disposed in the semiconductor substrate, wherein a first portion of the isolation structure is located between the first p-type doped region and the second p-type doped region in a first horizontal direction, an edge of the first n-type well region is located under the first portion of the isolation structure in the vertical direction, and a distance between the first p-type doped region and the edge of the first n-type well region in the first horizontal direction is less than a length of the first portion of the isolation structure in the first horizontal direction.

2. The ESD protection structure according to claim 1, wherein the first p-type doped region is an emitter of a bipolar junction transistor, and the second p-type doped region is at least a part of a collector of the bipolar junction transistor.

3. The ESD protection structure according to claim 2, wherein the emitter and a base of the bipolar junction transistor are electrically connected to a first terminal, and the collector of the bipolar junction transistor is electrically connected to a second terminal.

4. The ESD protection structure according to claim 3, wherein the first terminal is a power pad, and the second terminal is an input/output pad or a ground pad.

5. The ESD protection structure according to claim 1, wherein the distance between the first p-type doped region and the edge of the first n-type well region in the first horizontal direction is equal to or less than 45 nanometers.

6. The ESD protection structure according to claim 1, wherein the distance between the first p-type doped region and the edge of the first n-type well region in the first horizontal direction is a distance between a bottom of the first p-type doped region and the edge of the first n-type well region in the first horizontal direction.

7. The ESD protection structure according to claim 1, wherein an edge of the p-type well region is located under the first portion of the isolation structure in the vertical direction.

8. The ESD protection structure according to claim 7, wherein the edge of the first n-type well region is directly connected with the edge of the p-type well region.

9. The ESD protection structure according to claim 1, wherein a length of the second p-type doped region in the first horizontal direction is greater than a length of the first p-type doped region in the first horizontal direction.

10. The ESD protection structure according to claim 1, wherein an area of the second p-type doped region in the vertical direction is greater than an area of the first p-type doped region in the vertical direction.

11. The ESD protection structure according to claim 1, wherein a bottom of the first p-type doped region is coplanar with or higher than a bottom of the first portion of the isolation structure in the vertical direction.

12. The ESD protection structure according to claim 1, wherein a bottom of the second p-type doped region is coplanar with or higher than a bottom of the first portion of the isolation structure in the vertical direction.

13. The ESD protection structure according to claim 1, wherein the first p-type doped region is elongated in a second horizontal direction, and the second p-type doped region is elongated in the second horizontal direction.

14. The ESD protection structure according to claim 13, wherein the second horizontal direction is orthogonal to the first horizontal direction.

15. The ESD protection structure according to claim 1, wherein the p-type well region surrounds the first n-type well region in a top view of the ESD protection structure.

16. The ESD protection structure according to claim 1, wherein the isolation structure surrounds the first p-type doped region and the second p-type doped region in a top view of the ESD protection structure.

17. The ESD protection structure according to claim 1, further comprising:
a deep n-type well region disposed in the semiconductor substrate, wherein the first n-type well region and the p-type well region are located above the deep n-type well region in the vertical direction.

18. The ESD protection structure according to claim 17, further comprising:
a second n-type well region disposed in the semiconductor substrate and located above the deep n-type well region in the vertical direction; and
an n-type doped region disposed in the second n-type well region, wherein a second portion of the isolation structure is located between the second p-type doped region and the n-type doped region in the first horizontal direction.

19. The ESD protection structure according to claim 18, wherein the second n-type well region surrounds the first n-type well region and the p-type well region in a top view of the ESD protection structure.

20. The ESD protection structure according to claim 1, wherein the first portion of the isolation structure is directly connected with the first p-type doped region, the second p-type doped region, the first n-type well region, and the p-type well region.
